(19) United States
(12) Patent Application Publication
(10) Pub. No.: US 2026/0180542 A1
(43) Pub. Date: Jun. 25, 2026

(54) ACOUSTIC WAVE DEVICES WITH METAL TEMPERATURE COMPENSATION LAYER

(71) Applicant: Skyworks Global Pte. Ltd., Singapore (SG)

(72) Inventors: Michael David Hill, Emmitsburg, MD (US); Stefan Bader, Fort Collins, CO (US); Kwang Jae Shin, Yongin-si (KR); Rei Goto, Osaka-Shi (JP)

(21) Appl. No.: 19/425,695

(22) Filed: Dec. 18, 2025

Related U.S. Application Data
(60) Provisional application No. 63/736,136, filed on Dec. 19, 2024.
(60) Provisional application No. 63/736,163, filed on Dec. 19, 2024.

(51) Int. Cl. H03H 9/02; H03H 9/25; H03H 9/64

(52) U.S. Cl. CPC H03H 9/02102; H03H 9/02834; H03H 9/25; H03H 9/6483

(57) ABSTRACT

Acoustic wave devices, including bulk and surface acoustic wave devices, include a temperature compensation layer in thermal communication with a piezoelectric layer. The temperature compensation layer includes a metal having a positive temperature coefficient of elasticity.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### SUMMARY

In some aspects, the techniques described herein relate to a bulk acoustic wave device including: a first electrode; a second electrode; a piezoelectric layer between the first and second electrodes; and a temperature compensation layer in thermal communication with the piezoelectric layer and including a metal having a positive temperature coefficient of elasticity.

In some aspects, the techniques described herein relate to a bulk acoustic wave device wherein the temperature compensation layer has a temperature coefficient of elasticity greater than 10×10−6K−1.

In some aspects, the techniques described herein relate to a bulk acoustic wave device wherein the temperature compensation layer has a temperature coefficient of elasticity in a range between 50×10−6K−1 and 800×10−6K−1.

In some aspects, the techniques described herein relate to a bulk acoustic wave device wherein the temperature compensation layer has a temperature coefficient of elasticity in a range between 100×10−6K−1 and 800×10−6K−1.

In some aspects, the techniques described herein relate to a bulk acoustic wave device wherein the temperature compensation layer is a ferromanganese layer.

In some aspects, the techniques described herein relate to a bulk acoustic wave device wherein the ferromanganese layer includes an additive.

In some aspects, the techniques described herein relate to a bulk acoustic wave device wherein the additive is molybdenum.

In some aspects, the techniques described herein relate to a bulk acoustic wave device wherein the temperature compensation layer includes a ferromagnetic alloy, an antiferromagnetic alloy, a spin glass alloy, a gum metal, or a high entropy alloy.

In some aspects, the techniques described herein relate to a bulk acoustic wave device wherein the temperature compensation layer includes an iron-nickel alloy, a manganese-chromium alloy a cobalt-nickel-hafnium-titanium-zirconium alloy, a nickel-titanium alloy, a nickel-titanium-cobalt alloy, a nickel-titanium-cobalt-niobium alloy, an iron-manganese alloy, an iron-manganese-molybdenum alloy, or a titanium-niobium alloy.

In some aspects, the techniques described herein relate to a bulk acoustic wave device wherein the temperature compensation layer is positioned between the piezoelectric layer and the first electrode.

In some aspects, the techniques described herein relate to a bulk acoustic wave device wherein the first electrode is positioned between the temperature compensation layer and the piezoelectric layer.

In some aspects, the techniques described herein relate to a bulk acoustic wave device wherein the second electrode is positioned between the temperature compensation layer and the piezoelectric layer.

In some aspects, the techniques described herein relate to a bulk acoustic wave device wherein the temperature compensation layer is embedded in the first electrode or the second electrode.

In some aspects, the techniques described herein relate to a bulk acoustic wave device further including a support substrate and an acoustic reflector between the support substrate and the first electrode.

In some aspects, the techniques described herein relate to an acoustic wave filter for filtering a radio frequency signal, the acoustic wave filter including: a bulk acoustic wave device of any preceding claim; and a plurality of additional acoustic wave resonators, the bulk acoustic wave device and the plurality of additional acoustic wave resonators configured to filter the radio frequency signal.

In some aspects, the techniques described herein relate to a multiplexer for filtering radio frequency signals, the multiplexer including: a first filter including a bulk acoustic wave device of any preceding claim; and a second filter coupled to the first filter at a common node.

In some aspects, the techniques described herein relate to a radio frequency module including: a filter including a bulk acoustic wave device of any preceding claim; radio frequency circuitry; and a package structure enclosing the filter and the radio frequency circuitry.

In some aspects, the techniques described herein relate to a radio frequency system including: an antenna; a filter including a bulk acoustic wave device of any preceding claim; and an antenna switch configured to selectively electrically connect the antenna and a signal path that includes the filter.

In some aspects, the techniques described herein relate to a wireless communication device including: a radio frequency front end including a filter that includes a bulk acoustic wave device of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a bulk acoustic wave device of any preceding claim.

In some aspects, the techniques described herein relate to a surface acoustic wave device including: a piezoelectric layer; an interdigital transducer electrode in electrical communication with the piezoelectric layer; and a temperature compensation layer between the piezoelectric layer and the interdigital transducer electrode, the temperature compensation layer including a metal having a positive temperature coefficient of elasticity.

In some aspects, the techniques described herein relate to a surface acoustic wave device wherein the temperature compensation layer has a temperature coefficient of elasticity greater than 50×10-6K-1.

In some aspects, the techniques described herein relate to a surface acoustic wave device wherein the temperature compensation layer has a temperature coefficient of elasticity in a range between 50×10-6K-1 and 800×10-6K-1.

In some aspects, the techniques described herein relate to a surface acoustic wave device wherein the temperature compensation layer has a temperature coefficient of elasticity in a range between 100×10-6K-1 and 800×10-6K-1.

In some aspects, the techniques described herein relate to a surface acoustic wave device wherein the temperature compensation layer is a ferromanganese layer.

In some aspects, the techniques described herein relate to a surface acoustic wave device wherein the ferromanganese layer includes an additive.

In some aspects, the techniques described herein relate to a surface acoustic wave device wherein the additive is molybdenum.

In some aspects, the techniques described herein relate to a surface acoustic wave device wherein the temperature compensation layer includes a ferromagnetic alloy, an antiferromagnetic alloy, a spin glass alloy, a gum metal, or a high entropy alloy.

In some aspects, the techniques described herein relate to a surface acoustic wave device wherein the temperature compensation layer includes an iron-nickel alloy, a manganese-chromium alloy a cobalt-nickel-hafnium-titanium-zirconium alloy, a nickel-titanium alloy, a nickel-titanium-cobalt alloy, a nickel-titanium-cobalt-niobium alloy, an iron-manganese alloy, an iron-manganese-molybdenum alloy, or a titanium-niobium alloy.

In some aspects, the techniques described herein relate to a surface acoustic wave device wherein the temperature compensation layer is at least partially positioned in the piezoelectric layer.

In some aspects, the techniques described herein relate to a surface acoustic wave device wherein the interdigital transducer electrode is at least partially positioned in the piezoelectric layer.

In some aspects, the techniques described herein relate to a surface acoustic wave device further including a support substrate, wherein the piezoelectric layer is positioned between the support substrate and the temperature compensation layer.

In some aspects, the techniques described herein relate to a surface acoustic wave device further including an intermediate structure between the support substrate and the piezoelectric layer.

In some aspects, the techniques described herein relate to a surface acoustic wave device wherein the intermediate structure includes a trap-rich layer or an oxide layer.

In some aspects, the techniques described herein relate to an acoustic wave filter for filtering a radio frequency signal, the acoustic wave filter including: a surface acoustic wave device of any preceding claim; and a plurality of additional acoustic wave resonators, the surface acoustic wave device and the plurality of additional acoustic wave resonators configured to filter the radio frequency signal.

In some aspects, the techniques described herein relate to a multiplexer for filtering radio frequency signals, the multiplexer including: a first filter including a surface acoustic wave device of any preceding claim; and a second filter coupled to the first filter at a common node.

In some aspects, the techniques described herein relate to a radio frequency module including: a filter including a surface acoustic wave device of any preceding claim; radio frequency circuitry; and a package structure enclosing the filter and the radio frequency circuitry.

In some aspects, the techniques described herein relate to a radio frequency system including: an antenna; a filter including a surface acoustic wave device of any preceding claim; and an antenna switch configured to selectively electrically connect the antenna and a signal path that includes the filter.

In some aspects, the techniques described herein relate to a wireless communication device including: a radio frequency front end including a filter that includes a surface acoustic wave device of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a surface acoustic wave device of any preceding claim.

### BACKGROUND

### Technical Field

The disclosed technology relates to acoustic wave devices. Embodiments of this disclosure relate to acoustic wave devices with a temperature compensation layer including a metal having a positive temperature coefficient of elasticity.

### Description of Related Technology

An acoustic wave filter can include a plurality of acoustic wave resonators arranged to filter a radio frequency signal. Example acoustic wave resonators include surface acoustic wave (SAW) resonators and bulk acoustic wave (BAW) resonators. A SAW resonator can include an interdigital transductor electrode on a piezoelectric substrate. The SAW resonator can generate a surface acoustic wave on a surface of the piezoelectric layer on which the interdigital transductor electrode is disposed. In BAW resonators, acoustic waves propagate in a bulk of a piezoelectric layer. Example BAW resonators include film bulk acoustic wave resonators (FBARs) and BAW solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

In acoustic wave devices, temperature compensation can be desirable. For example, temperature compensated SAW (TCSAW) devices typically include a temperature compensation layer, such as a silicon dioxide layer, over and in contact with an interdigital transducer (IDT) electrode. Temperature compensated BAW (TCBAW) devices can also include a temperature compensation layer.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave device according to an embodiment.

FIGS. 1B to 1F are schematic cross-sectional side views of an active region of different BAW device stack configurations.

FIG. 2A is a schematic cross-sectional side view of a surface acoustic wave device according to an embodiment.

FIGS. 2B and 2C are schematic cross-sectional side views of surface acoustic wave device according to other embodiments.

FIG. 3A is a schematic diagram of a ladder filter that includes an acoustic wave resonator according to an embodiment.

FIG. 3B is schematic diagram of an acoustic wave filter.

FIGS. 4A, 4B, 4C, and 4D are schematic diagrams of multiplexers that includes an acoustic wave resonator according to an embodiment.

FIGS. 5, 6, and 7 are schematic block diagrams of modules that include a filter with an acoustic wave device according to an embodiment.

FIG. 8 is a schematic block diagram of a wireless communication device that includes a filter with an acoustic wave device according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave devices can include a temperature compensation layer. For example, bulk acoustic wave (BAW) resonators and filters are generally designed to operate within a temperature range of −40° C. to 150° C. Implementing frequency compensation across this temperature spectrum can enhance filter performance by optimizing, for example, roll-off characteristics, reducing insertion loss, and minimizing die size. A temperature compensation layer can bring the temperature coefficient of frequency (TCF) of an acoustic wave device closer to zero relative to a similar acoustic wave device without the temperature compensation layer. The temperature compensation layer can have a positive temperature coefficient of elasticity (TCE). This can compensate for a piezoelectric layer of the acoustic wave device having a negative TCF. The temperature compensation layer can be in physical contact with at least a portion of the piezoelectric layer of an acoustic wave device and/or with an electrode of an acoustic wave device. Certain bulk acoustic wave (BAW) devices include a temperature compensation layer between an electrode and a piezoelectric layer. Such BAW devices can be referred to as temperature compensated BAW (TCBAW) devices. Certain surface acoustic wave (SAW) devices include a temperature compensation layer over and in physical contact with an interdigital transducer (IDT) electrode. Such SAW devices can be referred to as temperature compensated SAW (TCSAW) devices.

A silicon dioxide (SiO₂) layer is used as a temperature compensation layer for an acoustic wave device in a variety of different applications. Such a silicon dioxide layer can also be referred to as amorphous silica or fused silica in various applications. Silicon dioxide is a material with an acoustic velocity and an elastic modulus that increase with temperature. This can allow for temperature compensation with piezoelectric materials that have an acoustic velocity and an elastic modulus that decrease with temperature.

However, fused silica such as SiO₂ presents limitations in acoustic wave filter stacks. As an electrical insulator, its placement in the stack is constrained. Moreover, fused silica can exhibit an acoustic loss tangent of up to about 0.03 at 5 GHz, making it a relatively high acoustic loss layer in the stack. This high acoustic loss negatively impacts the filter's performance, as low energy dissipation is essential for maintaining efficiency in acoustic wave filters. Additionally, the material's relatively low acoustic impedance makes it difficult to achieve optimal impedance matching in various stack configurations. Fused silica is also mechanically brittle, making it prone to fractures caused by thermal stresses, especially in high-power applications. These limitations in terms of electrical, acoustic, and mechanical properties make fused silica less ideal as a temperature compensating material for acoustic wave filters.

Previous approaches have utilized fused silica or doped fused silica for temperature compensation in these filters. Other brittle glasses, such as fused germania and fused tellurium oxide, have also been explored in the literature. However, these alternatives share similar drawbacks, including high resistivity, poor acoustic loss performance, low acoustic impedance, and mechanical brittleness, which limit their utility in acoustic wave filter applications.

Various embodiments disclosed herein relate to acoustic wave devices with a temperature compensation layer that includes a metal having a positive temperature coefficient of elasticity. Metallic materials with a positive temperature coefficient of elastic modulus are better conductors, have a lower acoustic loss and a higher acoustic impendence than fused silica enabling the temperature compensating layer to be placed within an electrode, for example. The metallic materials are ductile and better heat conductors than fused silica as well, making them well suited for high power applications. Any suitable principles and advantages disclosed herein can be implemented in any types of acoustic wave devices such as BAW devices, SAW devices, or timing devices with, for example, zero drift BAW or SAW resonators.

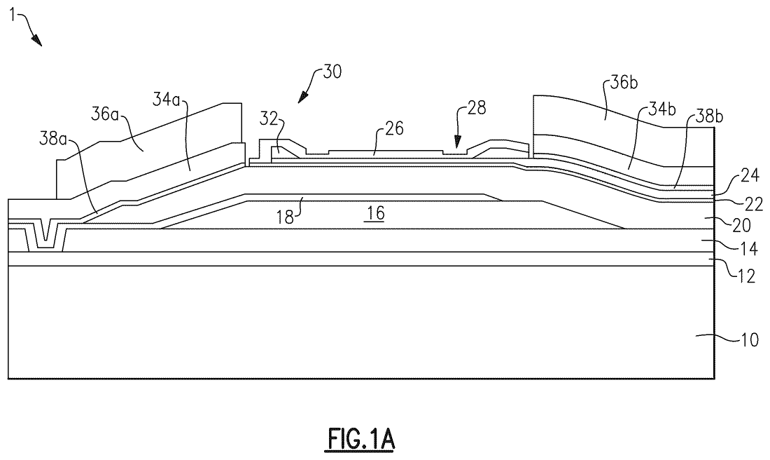

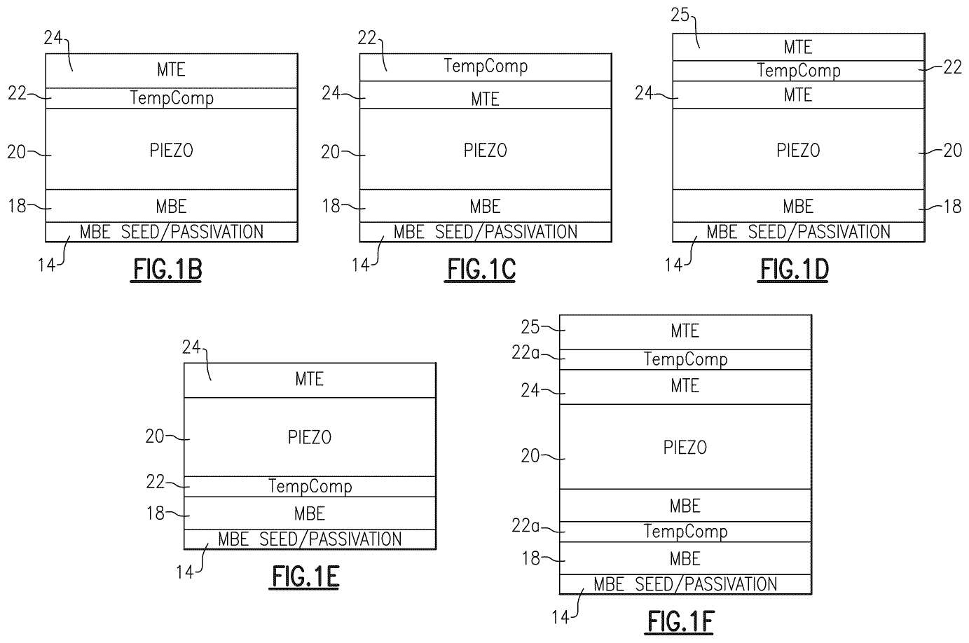

FIG. 1A is a schematic cross-sectional side view of a BAW device 1 according to an embodiment. The BAW device 1 includes a support substrate 10, a trap rich layer 12, a first passivation layer 14, a cavity 16, a first electrode 18, a piezoelectric layer 20, a temperature compensation layer 22, a second electrode 24, and a second passivation layer 26. The BAW device 1 also includes a recessed frame structure 28 and a raised frame structure 30. The temperature compensation layer 22 is a metal layer that has a positive temperature coefficient of elasticity.

The support substrate 10 can be a semiconductor substrate, such as a silicon substrate. The support substrate 10 can be a high resistivity silicon substrate. The support substrate 10 can be any other suitable support substrate, such as a substrate of quartz, silicon carbide, sapphire, glass, gallium arsenide, or any suitable ceramic (e.g., spinel, alumina, etc.).

The trap rich layer 12 can be a polysilicon layer, an amorphous silicon layer, or the like. The trap rich layer 12 can be positioned between the support substrate 10 and the first passivation layer 14. The first passivation layer 14 can be referred to as a lower passivation layer. The first passivation layer 14 can be a buried oxide layer. The first passivation layer 14 can be an amorphous silicon oxycarbide layer in certain applications. In some other applications, the first passivation layer 14 can be a silicon dioxide layer or any other suitable passivation layer, such as aluminum oxide, silicon carbide, aluminum nitride, silicon nitride, silicon oxynitride, or the like. In some instances, a silicon dioxide layer can be over a trap rich layer and an amorphous silicon oxycarbide layer can be over the silicon dioxide layer. In some embodiments, the first passivation layer 14 can be provided between the cavity 16 and the first electrode 18.

The cavity 16 is an example of an acoustic reflector. As illustrated in FIG. 1A, the air cavity 16 is located above the support substrate 10. The cavity 16 is positioned between the support substrate 10 and the first electrode 18. In some applications, a cavity can be etched into a support substrate. In certain applications, a solid acoustic mirror with alternating high acoustic impedance and low acoustic impedance can be included in place of an air cavity. A BAW device with an air cavity can be referred to as an FBAR. A BAW device with a solid acoustic mirror (SMR) can be referred to as a BAW SMR.

The first electrode 18 can be referred to as a lower electrode or a bottom electrode. The first electrode 18 can have a relatively high acoustic impedance. The first electrode 18 can include molybdenum (Mo), tungsten (W), ruthenium (Ru), chromium (Cr), iridium (Ir), platinum (Pt), Ir/Pt, or any suitable alloy and/or combination thereof. The second electrode 24 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 18 in certain instances. The second electrode 24 can be referred to as an upper electrode or a top electrode. The thickness of the first electrode 18 can be approximately the same as the thickness of the second electrode 24 in a main acoustically active region of the BAW device 1. The first electrode 18 and the second electrode 24 can be the only electrodes of the BAW device 1.

The piezoelectric layer 20 is positioned between the first electrode 18 and the second electrode 24. The piezoelectric layer 20 can include aluminum nitride or any other suitable piezoelectric material. The piezoelectric layer 20 can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain instances, the piezoelectric layer 20 can be an aluminum nitride layer doped with scandium. Doping the piezoelectric layer 20 can adjust resonant frequency. Doping the piezoelectric layer 20 can increase the coupling coefficient k² of the BAW device 1. Doping to increase the coupling coefficient k² can be advantageous for wide band devices and/or high frequency devices where the coupling coefficient k² may be limited due to a thin resonator stack including a relatively thin piezoelectric layer thickness.

The temperature compensation layer 22 can bring the TCF of the BAW device 1 closer to zero. The temperature compensation layer 22 can have a positive temperature coefficient of elasticity (TCE). The temperature compensation layer 22 can be in physical contact with the piezoelectric layer 20 as shown in FIG. 1A. The temperature compensation layer 22 can be in physical contact with an electrode of the BAW device (e.g., the second electrode 64 in FIG. 1A). The temperature compensation layer 22 can be positioned in any other locations in the BAW device 1. As illustrated, the temperature compensation layer 22 is positioned between an electrode of the BAW device 1 (e.g., the second electrode 64 in FIG. 1A) and the piezoelectric layer 20. In other embodiments, the temperature compensation layer 22 can be positioned (1) between a piezoelectric layer and upper electrode (e.g., as illustrated in FIG. 1A), (2) between the piezoelectric layer and lower electrode, (3) embedded within a piezoelectric layer, (4) embedded within an electrode, or (5) any suitable combination of (1) to (4).

The temperature compensation layer 22 can include any suitable metal that has a positive temperature coefficient of elasticity (TCE). Preferably, the temperature compensation layer 22 has a negative thermal expansion rate and/or a relatively high electrical conductivity. In some embodiments, the temperature compensation layer 22 may have a small positive or negative rate of thermal expansion. During martensitic transitions, the crystal structure can change and the TCE can become negative in certain lattice directions. However, at the same time, volume TCE may stay positive. In strongly textured thin films such change may not be an advantage change.

Shape memory alloys (SMAs) and other systems exhibiting a Martensite/Austenite phase transition can experience significant, sometimes sharp, changes in elastic modulus during heating or cooling. In most of these materials, the high-temperature Austenite phase exhibits a higher elastic modulus compared to the low-temperature Martensite phase. This transition is accompanied not only by hysteresis in the elastic modulus vs. temperature relationship but also in the stress vs. strain curve, indicating that the Martensite/Austenite phase shift can be initiated by changes in temperature, stress, or a combination of both. The exact range of the Martensite/Austenite transition in terms of temperature and/or stress varies depending on the specific alloy system and processing history, including factors such as annealing, plastic deformation, and thermal cycling. It can be desirable to include an alloy that has a narrow hysteresis and a wide Martensite/Austenite transition range in the temperature compensation layer 22 to smoothen the elastic constant change over the desired temperature range and avoid a sudden change of the elastic modulus with changing temperature and damping losses due to the wide hysteresis.

In some embodiments, the temperature compensation layer 22 can include a positive temperature coefficient Elinvar-like metal. Elinvar-like metals can include, for example, ferromagnetic alloys (e.g., a Fe-Ni alloy), antiferromagnetic alloys (e.g., a Mn-Cr alloy), spin glass alloys, gum metals, or high entropy alloys (e.g., a Co-Ni-Hf-Ti-Zr alloy). In some embodiments, the temperature compensation layer 22 can be a ferromanganese layer. The ferromanganese can include additives such as molybdenum. For example, the ferromanganese layer can include less than 25%, less than 24%, less than 23%, or less than 22% of manganese content. Such manganese content can be significant in providing the ferromanganese layer with a positive temperature coefficient of elasticity.

In some embodiments, the temperature compensation layer 22 can be a nickel-titanium (NiTi) layer. The nickel titanium layer may be in a stable phase such that it has a positive TCE. The ratio of nickel and titanium in a nickel-titanium alloy can be, for example, Ti(50%-x)-Ni(50%+x) where x is in a range of 3≤x≤3. In some embodiments, the temperature compensation layer 22 can include a nickel-titanium-cobalt alloy. The ratio of titanium, nickel, and cobalt in a nickel-titanium-cobalt alloy can be, for example, Ti(50%)Ni(50%-x)Co(x) where x is in a range of 2.5≤x≤12. In some embodiments, the temperature compensation layer 22 can include a nickel-titanium-cobalt-niobium alloy. The ratio of nickel, titanium, cobalt, and niobium in a nickel-titanium-cobalt-niobium alloy can be, for example, Ti (50%-x)Ni(50%-y)Co(y)Nb(x) where x is in a range of 0≤x≤5 and y is in a range of 2.5≤x≤12. In some embodiments, the temperature compensation layer 22 can include an iron-manganese alloy. The ratio of iron and manganese in an iron-manganese alloy can be, for example, Fe(100%-x)Mn(x) where x is in a range of 18≤x≤27. In some embodiments, the temperature compensation layer 22 can include an iron-manganese-molybdenum alloy. The ratio of iron, manganese, and molybdenum in an iron-manganese-molybdenum alloy can be, for example, Fe(100%-x-y)Mn(x)Mo(y) where x is in a range of 18≤x≤12 and y is in a range of 0≤x≤5. In some embodiments, the temperature compensation layer 22 can include a titanium-niobium alloy.

The high entropy alloys, such as a Co-Ni-Hf-Ti-Zr alloy can have a positive TCE from room temperature to 900 k with an elastic modulus of around 90-100 GPa at room temperature. The loss tangent of the Co-Ni-Hf-Ti-Zr alloy can be significantly smaller as compared to silicon dioxide and shape memory alloys. Such characteristics of the Co-Ni-Hf-Ti-Zr alloy can be beneficial when used as the temperature compensation layer 22. The ratio of cobalt, nickel, hafnium, titanium, and zirconium in a Co-Ni-Hf-Ti-Zr alloy can be, for example, Co(25%±2)Ni(25%±2)Hf(16.667%±2)Ti(16.667%±2)Zr(16.666%±2).

In some embodiments, the temperature compensation layer 22 can have a TCE greater than greater than 40×10⁻⁶K⁻¹, greater than 50×10⁻⁶K⁻¹, or greater than 100×10⁻⁶K⁻¹. For example, the TCE of the temperature compensation layer 22 can be in a range between 50×10⁻⁶K⁻¹ and 800×10^{×6}K^{×1}, 100×10⁻⁶K⁻¹ and 800×10⁻⁶K^{×1}, or 200×10⁻⁶K⁻¹ and 800×10^{×6}K⁻¹. The temperature compensation layer 22 can have any suitable thickness depending at least in part on the resonator frequency, a total stack thickness, and or the material of the temperature compensation layer 22. In some embodiments, the temperature compensation layer 2 that includes the Co-Ni-Hf-Ti-Zr alloy can have a thickness in a range between 5 nm and 200 nm, 25 nm and 200 nm, or 25 nm and 100 nm.

The second passivation layer 26 can be referred to as an upper passivation layer. The second passivation layer 26 can be referred to as a passivation and trimming layer, as the second passivation layer 26 can be used for both passivation and frequency trimming. The second passivation layer 26 can be a silicon oxycarbide layer, a silicon dioxide layer, or any other suitable passivation layer. The second passivation layer 26 can be the same material as the first passivation layer 26 in certain instances. The second passivation layer 26 can have different thicknesses in different regions of the BAW device 1. Part of the second passivation layer 26 can form at least part of the recessed frame structure 28 and/or the raised frame structure 30. In some embodiments, the raised frame structure 30 can include a raised frame layer 32. For example, the raised frame structure can include a metal layer or a dielectric layer.

An active region or active domain of the BAW device 1 can be defined by a portion of the piezoelectric layer 20 that overlaps an acoustic reflector, such as the air cavity 16, and is between the first electrode 18 and the second electrode 24. The temperature compensation layer 22 can be positioned at least in the active region of the BAW device 1. The active region can correspond to where voltage is applied on opposing sides of the piezoelectric layer 20 over the acoustic reflector. The active region can be the acoustically active region of the BAW device 1. The BAW device 1 also includes a recessed frame region with the recessed frame structure 28 in the active region and a raised frame region with the raised frame structure 30 in the active region. The raised frame structure 30 can also include an oxide layer. The main acoustically active region can provide a main mode of the BAW device 1. The main acoustically active region can be the central part of the active region that is free from frame structures, such as the recessed frame structure 28 and the raised frame structure 30.

While the BAW device 1 includes the recessed frame structure 28 and the raised frame structure 30, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more metal layers 34a, 34b, 36a, 36b can connect an electrode of the BAW device 1 to one or more other BAW devices, one or more integrated passive devices, one or more other circuit elements, one or more signal ports, the like, or any suitable combination thereof. The metal layers 34a and 36a can be electrically connected to the first electrode 18, and the metal layers 34b and 36b can be electrically connected to the second electrode 24. Portions of an adhesion layer 38a and 38b can be positioned between the corresponding metal layer 38a, 38b and an underlying layer (e.g., the piezoelectric layer 20 or the second electrode 24) to increase adhesion between the layers. The adhesion layer can be a titanium layer, for example.

The temperature compensation layer 22 can be positioned in any suitable locations in a BAW device stack. FIGS. 1B to 1F are schematic cross-sectional side views of an active region of different BAW device stack configurations.

In FIG. 1B, the BAW device stack includes a passivation layer 14, a first electrode 18 over the passivation layer 14, a piezoelectric layer 20 over the first electrode 18, a temperature compensation layer 22 over the piezoelectric layer 20, and a second electrode 24 over the temperature compensation layer 22.

In FIG. 1C, the BAW device stack includes a passivation layer 14, a first electrode 18 over the passivation layer 14, a piezoelectric layer 20 over the first electrode 18, a second electrode 24 over the piezoelectric layer 20, and a temperature compensation layer 22 over the second electrode layer 24.

In FIG. 1D, the BAW device stack includes a passivation layer 14, a first electrode 18 over the passivation layer 14, a piezoelectric layer 20 over the first electrode 18, a second electrode 24 over the piezoelectric layer 20, a temperature compensation layer 22 over the second electrode layer 24, and a third electrode layer 25 over the temperature compensation layer 22.

In FIG. 1E, the BAW device stack includes a passivation layer 14, a first electrode 18 over the passivation layer 14, a temperature compensation layer 22 over the first electrode 18, a piezoelectric layer 20 over the temperature compensation layer 22, and a second electrode 24 over the piezoelectric layer 20. In some embodiments, the temperature compensation layer 22 can be relatively thin. For example, the temperature compensation layer 22 can be thinner than the first electrode 18 or the second electrode 24. In some other embodiments, the temperature compensation layer 22 can be relatively thick. For example, the temperature compensation layer 22 can be thicker than the first electrode 18 or the second electrode 24.

In FIG. 1F, the BAW device stack includes a passivation layer 14, a first electrode 18 over the passivation layer 14, a first temperature compensation layer 22a over the first electrode 18, a piezoelectric layer 20 over the first temperature compensation layer 22a, a second electrode 24 over the piezoelectric layer 20, a second temperature compensation layer 22b over the second electrode 24, a third electrode 25 over the second temperature compensation layer 22b, and a fourth electrode 23 between the first temperature compensation layer 22a and the piezoelectric layer 20.

Any suitable number of temperature compensation layer(s) can be provided at any suitable location in a BAW device stack. The BAW device 1 with the temperature compensation layer 22 can overcome the above provided problems related to using a silicon oxide layer as a temperature compensation layer. The BAW device 1 with the temperature compensation layer 22 can be suited for high power applications. Any suitable principles and advantages related to a temperature compensation layer disclosed herein can be implemented in any other types of acoustic wave devices such as SAW devices.

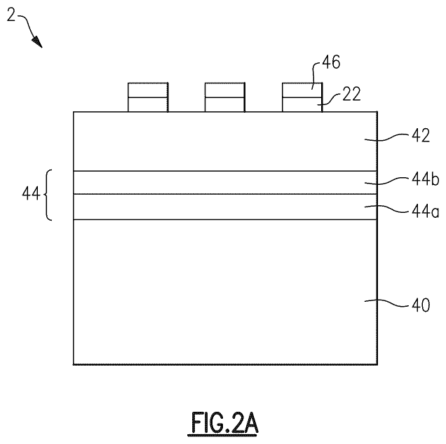

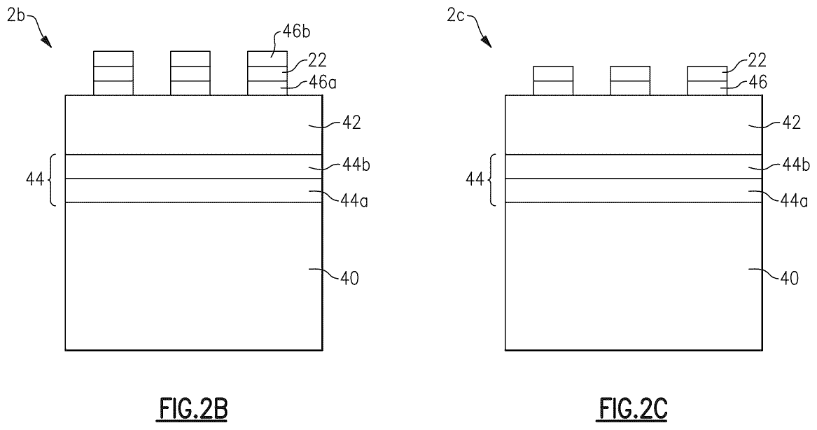

FIG. 2A is a schematic cross-sectional side view of a SAW device 2a according to an embodiment. Unless otherwise noted, the components of the SAW device 2a shown in FIG. 2A may be structurally and/or functionally the same as or generally similar to like components disclosed herein. The SAW device 2a includes the temperature compensation layer 22.

The SAW device 2a is an example of a multilayer piezoelectric substrate surface acoustic wave (MPS-SAW) device. The SAW device 1 can include a multi-layer piezoelectric substrate (MPS) that includes a support substrate 40, a piezoelectric layer 42, and an intermediate structure 44 between the support substrate 40 and the piezoelectric layer 42. The support substrate 40 and the intermediate structure 44 can be part of a support structure of the MPS. The SAW device 1 can also include an interdigital transducer (IDT) electrode 46 in electrical communication with the piezoelectric layer 42. The temperature compensation layer 22 can be positioned between the piezoelectric layer 42 and the IDT electrode 46.

The support substrate 40 can be any suitable substrate layer, such as a silicon layer. The support substrate 40 can have a relatively high acoustic impedance. An acoustic impedance of the support substrate 40 can be higher than an acoustic impedance of the piezoelectric layer 42. For instance, the support substrate 40 can have a higher acoustic impedance than an acoustic impedance of lithium niobate and a higher acoustic impedance than lithium tantalate. The acoustic impedance of the support substrate 40 can be higher than an acoustic impedance of silicon dioxide (SiO₂). The SAW resonator 2 including the piezoelectric layer 42 on a support substrate 40 with relatively high thermal conductivity, such as silicon substrate, can achieve better thermal dissipation compared to a similar SAW resonator without the high impedance support substrate 40.

The piezoelectric layer 42 can include any suitable piezoelectric layer, such as a lithium based piezoelectric layer. In some embodiments, the piezoelectric layer 42 can be a lithium tantalate (LT) layer. For example, the piezoelectric layer 42 can be an LT layer having a cut angle of 20° (20°Y-cut X-propagation LT) or a cut angle of 60° (60°Y-cut X-propagation LT). For example, the piezoelectric layer 42 can be 20±10° Y-cut LT, 42±25°Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 42. For example, the piezoelectric layer 42 can be an LN layer having a cut angle of about 118° (118° Y-cut X-propagation LN) or more or a cut angle of about 132° (132Y-cut X-propagation LN) or less. For example, the piezoelectric layer 42 can be 125±20° Y-cut LN, 125±15° Y-cut LN, 125±10° Y-cut LN, or 125±5° Y-cut LN. A thickness of the piezoelectric layer 42 can be selected based on a wavelength λ or L of a surface acoustic wave generated by the SAW device 2a in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 42 can be sufficiently thick to avoid significant frequency variation. For example, the thickness of the piezoelectric layer 42 can be in a range of 0.1 L to 0.5, 0.1 L to 0.3 L, or 0.1 L to 0.2 L. Selecting the thickness of the piezoelectric layer 42 from these ranges can be critical in avoiding significant frequency variation and providing sufficient temperature coefficient of frequency for the SAW device 2a. In some embodiments, the piezoelectric layer 42 can include lithium tantalate (LT) and lithium niobate (LN).

In some embodiments, the intermediate structure 44 can include, for example, a trap-rich layer 44a and a functional layer 44b. The trap-rich layer 44a can be a polysilicon layer, an amorphous silicon layer, or the like. The trap-rich layer 44a can have a reduced carrier mobility relative to the support substrate 40. The trap-rich layer 44a can improve the electrical characteristics of the SAW device 2a by increasing the depth and sharpness on the anti-resonance peak. The functional layer 44b can act as an adhesive layer. The functional layer 44b can be, for example, an oxide layer (e.g., a silicon dioxide (SiO₂) layer). The functional layer 44b can enhance energy confinement and TCF tunability.

The IDT electrode 46 can include any suitable material. The IDT electrode 46 may include one or more other metals, such as aluminum (Al), copper (Cu), Magnesium (Mg), titanium (Ti), molybdenum (Mo), tungsten (W), etc. The IDT electrode 46 may include alloys, such as AlMgCu, AlCu, etc.

Although the IDT electrode 46 of FIG. 2A is illustrated as having a single layer, an IDT electrode can have two or more layers in some other embodiments. For example, a dual layer IDT electrode can include a first layer and a second layer. The first layer of the IDT electrode can be referred to as a lower electrode layer. The first layer of the IDT electrode can be disposed between the second layer of the IDT electrode and the piezoelectric layer 42. The first layer of the IDT electrode can be disposed between the second layer of the IDT electrode and the temperature compensation layer 22. In some embodiments, the temperature compensation layer 22 may be positioned between the first and second layers of the dual layer IDT electrode. Any suitable principles and advantages disclosed herein may be applied with multi-layer IDT electrodes that include three or more IDT layers.

The temperature compensation layer 22 can bring the TCF of the SAW device 2a closer to zero. The temperature compensation layer 22 can have a positive TCF. The temperature compensation layer 22 can positioned between the piezoelectric layer 42 and the IDT electrode 46. The temperature compensation layer 22 of FIG. 2A can include the same material as or have the same or generally similar functions as the temperature compensation layer 22 of FIG. 1A. The temperature compensation layer 22 can have a thickness in a range between, for example, 10 nm and 300 nm, 50 nm and 300 nm, or 50 nm and 200 nm.

The temperature compensation layer 22 and/or the IDT electrode 46 can be formed with (e.g., formed on or at least partially in) the piezoelectric layer 42. The piezoelectric layer 42, the temperature compensation layer 22, and the IDT electrode 46 can be provided in any suitable manner. For example, the piezoelectric layer 42, the temperature compensation layer 22, and the IDT electrode 46 can be provided in sequence. When the temperature compensation layer 22 and/or the IDT electrode are/is provided at least partially in the piezoelectric layer 42, the piezoelectric layer 42 can be partially etched and/or provided in a plurality of steps.

The SAW device 2a with the temperature compensation layer 22 can improve the TCF of the SAW device 2a. When a dielectric layer, such as a silicon oxide layer, is used as a temperature compensation layer between the piezoelectric layer 42 and the IDT electrode 46, the coupling coefficient k² can degrade due to insufficient electro flux into the piezoelectric layer 42. However, the temperature compensation layer 22 can avoid or mitigate the k² degradation. Also, the temperature compensation layer 22 may enable the functional layer 44b to be thinner, thereby improving the Q.

The temperature compensation layer 22 can be positioned in any suitable locations in a SAW device stack. FIGS. 2B and 2C are schematic cross-sectional side views of SAW devices 2b, 2c that include a temperature compensation layer, according to various embodiments. Unless otherwise noted, the components of the SAW devices 2b, 2c shown in FIGS. 2B and 2C may be structurally and/or functionally the same as or generally similar to like components disclosed herein.

In the SAW device 2b of FIG. 2B, the temperature compensation layer 22 is positioned between a first IDT electrode layer 46a and a second IDT electrode layer 46b. The combination of the first and second IDT electrode layers 46a, 46b is an example of a dual layer IDT structure. In some other embodiments, there may be more than two IDT electrode layers. In some embodiments, the first IDT electrode layer 46a can function as an adhesion layer or a lattice constant matching metal layer for matching lattice constants between a surface of the piezoelectric layer 42 and the temperature compensation layer 22. The second IDT electrode layer 46b may help to improve the quality (e.g., grain size, roughness, etc.) of the temperature compensation layer 22 to improve power durability and/or electrical performance.

In the SAW device 2c of FIG. 2C, the temperature compensation layer 22 is positioned over the IDT electrode 46. Although a single layer IDT electrode is shown in FIG. 2C, the temperature compensation layer 22 can be positioned over a multi-layer IDT electrode structure.

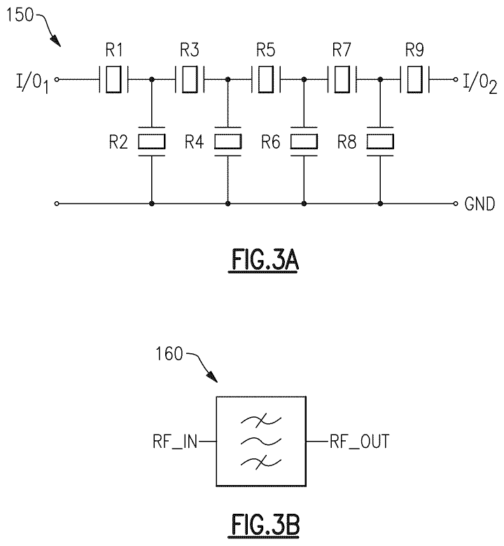

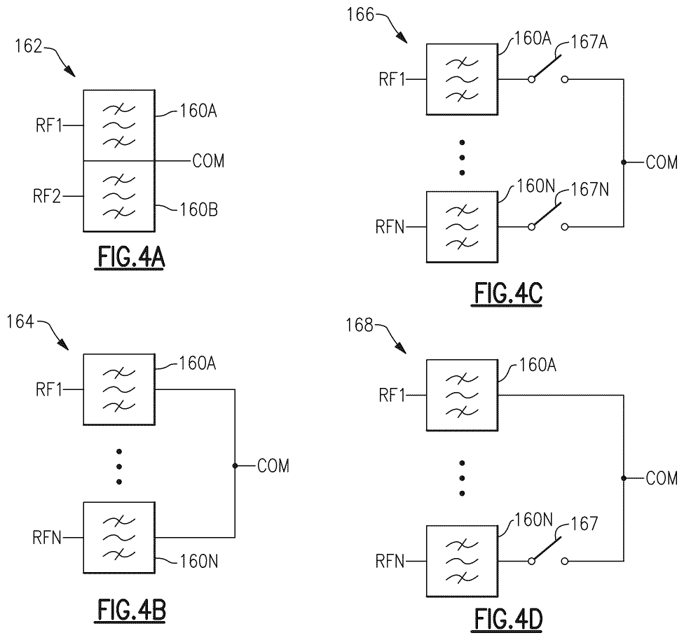

Acoustic wave devices disclosed herein can be implemented as acoustic wave resonators in a variety of filters. Such filters can be arranged to filter a radio frequency signal. Acoustic wave devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 3A.

FIG. 3A is a schematic diagram of a ladder filter 150 that includes an acoustic wave resonator according to an embodiment. The ladder filter 150 is an example topology that can implement a band pass filter formed of acoustic wave resonators. In a band pass filter with a ladder filter topology, the shunt resonators can have lower resonant frequencies than the series resonators. The ladder filter 150 can be arranged to filter a radio frequency signal. As illustrated, the ladder filter 150 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be in included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 150 can include an acoustic wave device including a silicon oxycarbide layer in accordance with any suitable principles and advantages disclosed herein. All acoustic resonators of the ladder filter 150 can include a silicon oxycarbide layer in accordance with any suitable principles and advantages disclosed herein in certain applications.

A filter that includes an acoustic wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio—Dual Connectivity (ENDC) application. A multiplexer including any such filters can include one or more other filters with a passband corresponding to a 5G NR operating band and/or a 4G LTE operating band.

FIG. 3B is schematic diagram of an acoustic wave filter 160. The acoustic wave filter 160 can include the acoustic wave resonators of the ladder filter 150. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes an acoustic wave resonator according to an embodiment.

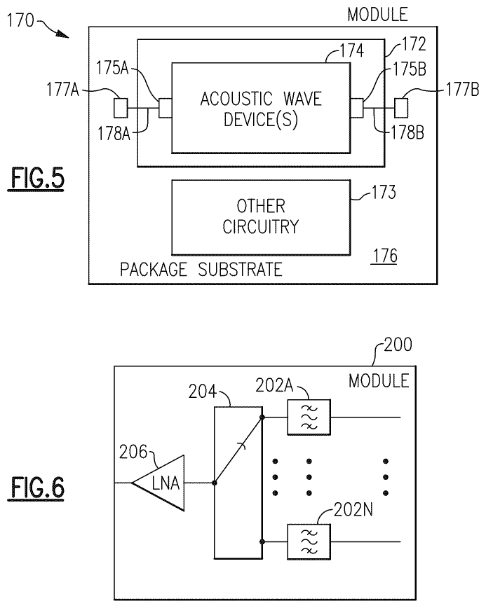

The acoustic wave devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 4A to 4D. Any suitable principles and advantages of these multiplexers can be implemented together with each other.

FIG. 4A is a schematic diagram of a duplexer 162 that includes an acoustic wave filter according to an embodiment. The duplexer 162 includes a first filter 160A and a second filter 160B coupled to together at a common node COM. One of the filters of the duplexer 162 can be a transmit filter and the other of the filters of the duplexer 162 can be a receive filter. In some other instances, such as in a diversity receive application, the duplexer 162 can include two receive filters. Alternatively, the duplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A includes an acoustic wave resonator in accordance with any suitable principles and advantages disclosed herein.

The second filter 160B can be any suitable filter arranged to filter a second radio frequency signal. The second filter 160B can be, for example, an acoustic wave filter, an acoustic wave filter that includes an acoustic wave resonator with at least one silicon oxycarbide layer, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 4B is a schematic diagram of a multiplexer 164 that includes an acoustic wave filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A includes an acoustic wave resonator in accordance with any suitable principles and advantages disclosed herein. The other filter(s) of the multiplexer 164 can include one or more acoustic wave filters, one or more acoustic wave filters that include an acoustic wave resonator in accordance with any suitable principles and advantages disclosed herein, one or more LC filters, one or more hybrid acoustic wave LC filters, the like, or any suitable combination thereof.

FIG. 4C is a schematic diagram of a multiplexer 166 that includes an acoustic wave filter according to an embodiment. The multiplexer 166 is like the multiplexer 164 of FIG. 4B, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 4D is a schematic diagram of a multiplexer 168 that includes an acoustic wave filter according to an embodiment. The multiplexer 168 illustrates that a multiplexer can include any suitable combination of hard multiplexed and switched multiplexed filters. One or more acoustic wave devices in accordance with any suitable principles and advantages disclosed herein can be included in a filter (e.g., the filter 160A) that is hard multiplexed to the common node COM of the multiplexer 168. Alternatively or additionally, one or more acoustic wave devices in accordance with any suitable principles and advantages disclosed herein can be included in a filter (e.g., the filter 160N) that is switch multiplexed to the common node COM of the multiplexer 168.

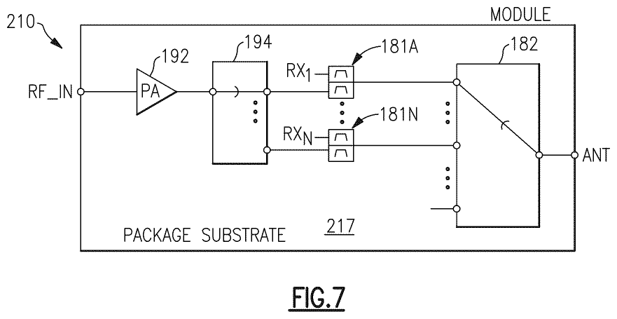

Acoustic wave devices disclosed herein can be implemented in a variety of packaged modules. Some example packaged modules will now be disclosed in which any suitable principles and advantages of the acoustic wave devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 5 to 7 are schematic block diagrams of illustrative packaged modules according to certain embodiments. Any suitable combination of features of these packaged modules can be implemented with each other.

FIG. 5 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include an acoustic wave filter that includes a plurality of acoustic wave devices, for example. The acoustic wave devices can be BAW devices in certain applications.

The acoustic wave component 172 shown in FIG. 5 includes one or more acoustic wave devices 174 and terminals 175A and 175B. The one or more acoustic wave devices 174 include at least one acoustic wave device implemented in accordance with any suitable principles and advantages disclosed herein. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 5. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more radio frequency (RF) couplers, one or more delay lines, one or more phase shifters, the like, or any suitable combination thereof. Accordingly, the other circuitry 173 can include one or more radio frequency circuit elements. The other circuitry 173 can be radio frequency circuitry. The other circuitry 173 can be electrically connected to the one or more acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 6 is a schematic block diagram of a module 200 that includes filters 202A to 202N, a radio frequency switch 204, and a low noise amplifier 206 according to an embodiment. One or more filters of the filters 202A to 202N can include any suitable number of acoustic wave devices in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

FIG. 7 is a schematic diagram of a radio frequency module 210 that includes an acoustic wave filter according to an embodiment. As illustrated, the radio frequency module 210 includes duplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 7 and/or additional elements. The radio frequency module 210 may include any one of the acoustic wave filters that include at least one acoustic wave resonator in accordance with any suitable principles and advantages disclosed herein.

The duplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave device in accordance with any suitable principles and advantages disclosed herein. Similarly, one or more of the receive filters can include an acoustic wave device in accordance with any suitable principles and advantages disclosed herein. Although FIG. 7 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the duplexers 181A to 181N. In some instances, the radio frequency switch 194 can electrically connect the output of the power amplifier 192 to more than one of the transmit filters. The antenna switch 182 can selectively couple a signal from one or more of the duplexers 181A to 181N to an antenna port ANT. The duplexers 181A to 181N can be associated with different frequency bands and/or different modes of operation (e.g., different power modes, different signaling modes, etc.).

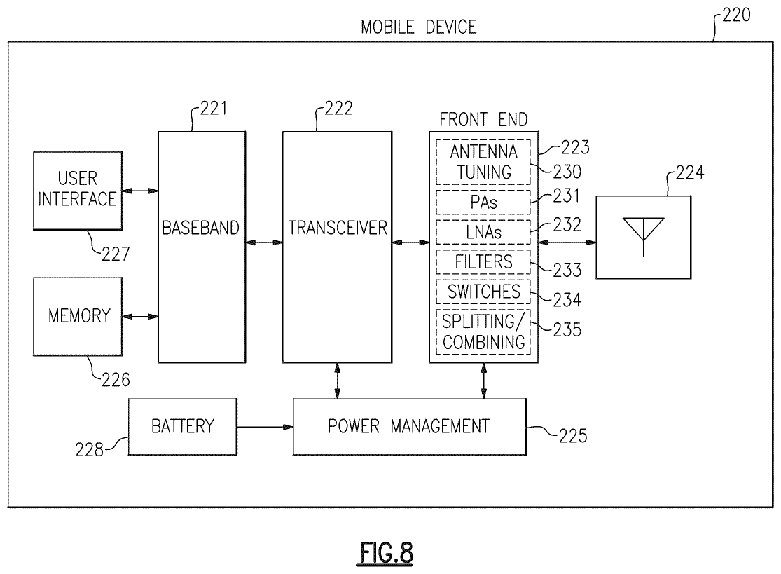

The acoustic wave devices disclosed herein can be implemented in wireless communication devices. FIG. 8 is a schematic block diagram of a wireless communication device 220 that includes an acoustic wave device according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 8 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 8, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 8, the power management system 225 receives a battery voltage from the battery 228. The battery 228 can be any suitable battery for use in the wireless communication device 220, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in a frequency range from about 2 GHz to 10 GHz, or in a frequency range from 5GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first electrode;
a second electrode;
a piezoelectric layer between the first and second electrodes; and
a temperature compensation layer in thermal communication with the piezoelectric layer and including a metal having a positive temperature coefficient of elasticity.

2. The bulk acoustic wave device of claim 1 wherein the temperature compensation layer has a temperature coefficient of elasticity in a range between 50×10^{×6}K^{'1} and 800×10⁻⁶K⁻¹.

3. The bulk acoustic wave device of claim 1 wherein the temperature compensation layer has a temperature coefficient of elasticity in a range between 100×10⁻⁶K⁻¹ and 800×10⁻⁶K⁻¹.

4. The bulk acoustic wave device of claim 1 wherein the temperature compensation layer is a ferromanganese layer.

5. The bulk acoustic wave device of claim 1 wherein the temperature compensation layer includes a ferromagnetic alloy, an antiferromagnetic alloy, a spin glass alloy, a gum metal, or a high entropy alloy.

6. The bulk acoustic wave device of claim 1 wherein the temperature compensation layer includes an iron-nickel alloy, a manganese-chromium alloy a cobalt-nickel-hafnium-titanium-zirconium alloy, a nickel-titanium alloy, a nickel-titanium-cobalt alloy, a nickel-titanium-cobalt-niobium alloy, an iron-manganese alloy, an iron-manganese-molybdenum alloy, or a titanium-niobium alloy.

7. The bulk acoustic wave device of claim 1 wherein the temperature compensation layer is positioned between the piezoelectric layer and the first electrode.

8. The bulk acoustic wave device of claim 1 wherein the first electrode and the second electrode are positioned between the temperature compensation layer and the piezoelectric layer.

9. The bulk acoustic wave device of claim 1 wherein the temperature compensation layer is embedded in the first electrode or the second electrode.

10. The bulk acoustic wave device of claim 1 further comprising a support substrate and an acoustic reflector between the support substrate and the first electrode.

11. A radio frequency module comprising:
a filter including a bulk acoustic wave device including a first electrode, a second electrode, a piezoelectric layer between the first and second electrodes, and a temperature compensation layer in thermal communication with the piezoelectric layer and including a metal having a positive temperature coefficient of elasticity;
radio frequency circuitry; and
a package structure enclosing the filter and the radio frequency circuitry.

12. A surface acoustic wave device comprising:
a piezoelectric layer;
an interdigital transducer electrode in electrical communication with the piezoelectric layer; and
a temperature compensation layer between the piezoelectric layer and the interdigital transducer electrode, the temperature compensation layer including a metal having a positive temperature coefficient of elasticity.

13. The surface acoustic wave device of claim 12 wherein the temperature compensation layer has a temperature coefficient of elasticity in a range between 50×10⁻⁶K⁻¹ and 800×10⁻⁶K⁻¹.

14. The surface acoustic wave device of claim 12 wherein the temperature compensation layer has a temperature coefficient of elasticity in a range between 100×10⁻⁶K⁻¹ and 800×10⁻⁶K⁻¹.

15. The surface acoustic wave device of claim 12 wherein the temperature compensation layer is a ferromanganese layer.

16. The surface acoustic wave device of claim 12 wherein the temperature compensation layer includes a ferromagnetic alloy, an antiferromagnetic alloy, a spin glass alloy, a gum metal, or a high entropy alloy.

17. The surface acoustic wave device of claim 12 wherein the temperature compensation layer includes an iron-nickel alloy, a manganese-chromium alloy a cobalt-nickel-hafnium-titanium-zirconium alloy, a nickel-titanium alloy, a nickel-titanium-cobalt alloy, a nickel-titanium-cobalt-niobium alloy, an iron-manganese alloy, an iron-manganese-molybdenum alloy, or a titanium-niobium alloy.

18. The surface acoustic wave device of claim 12 wherein the temperature compensation layer is at least partially positioned in the piezoelectric layer.

19. The surface acoustic wave device of claim 12 wherein the interdigital transducer electrode is at least partially positioned in the piezoelectric layer.

20. A radio frequency module comprising a filter, the filter including the surface acoustic wave device of claim 12.
